(19) United States
(12) Patent Application Publication
(10) Pub. No.: US 2026/0144138 A1
(43) Pub. Date: May 21, 2026

(54) STIFFENER FOR PACKAGE MINIATURIZATION

(71) Applicant: Intel Corporation, Santa Clara, CA (US)

(72) Inventors: R Selvakumar RAJA GOPAL, Tapah (MY); Seok Ling LIM, Penang (MY); Bok Eng CHEAH, Gelugor (MY); Shui Lei NG, Taiping (MY); Dhinesh A/L SASIDARAN, Bayan Lepas (MY)

(21) Appl. No.: 18/951,703

(22) Filed: Nov. 19, 2024

(51) Int. Cl. H01L 23/18; H01L 21/48; H01L 23/00; H01L 23/31; H01L 23/498; H01L 25/065

(52) U.S. Cl. CPC H10W 76/42; H10W 70/093; H10W 70/65; H10W 74/117; H10W 90/00; H10W 90/701; H10W 72/874; H10W 90/22; H10W 90/722; H10W 90/724

(57) ABSTRACT

The present disclosure generally relates to a device including a substrate including a first surface and a second surface opposite to the first surface, a base die including dies formed on the base die, wherein the base die is electrically coupled to the first surface, and a stiffener adhered to the first surface, wherein the stiffener is peripherally configured to the base die, wherein the stiffener includes a first interconnect which extends through the stiffener from a first stiffener surface to a second stiffener surface, wherein the first interconnect is electrically coupled to the base die via a metal trace embedded in the substrate. A method for forming the device is also described.

### BACKGROUND

Traditionally, disaggregated die architecture introduces additional complexity at the package level during production testing. Every die within the package may be required to undergo testing, and that each die may have to be tested independently from the others to achieve the objective of parallel testing. Implementing a parallel testing strategy requires that the test-specific pins of each die be accessible via the package's external pins, which results in an increased number of total pins on the package hence increase the package footprint and cost.

Traditional methods for addressing the above may involve decreasing the number of pins dedicated to scan test ports (reducing high performance test port (HPTP) pin count), which may undesirably narrow the data transfer width and impacts the duration of the test. Also, traditional devices may have adopted a strategy to adapt the use of sort-only die bumps as an attempt to reduce testing time. This approach may involve cutting the number of test port pins by half for dies that tend to be not critical in terms of test time. For example, it may avoid testing dies that encounter considerably long or overly short testing duration, premised on an overly general criterion just to save time. While this strategy may alleviate packaging constraints to some degree, it may be susceptible to incorrectly sacrificing or failing to enable testing of dies that may be critical, such as central processing unit (CPU) dies, just to achieve a considerable reduction in test time and to deal with limited space available on the package for test pins.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIG. 1 shows an architecture of dies in a traditional electronic device wherein each die has its individual test pin for parallel testing;

FIG. 2A shows a top view of a traditional electronic device, depicting the die layout;

FIG. 2B shows cross-sectional view of the electronic device of FIG. 2A;

FIG. 3A shows a top view of a device of the present disclosure, particularly showing the layout of a stiffener, ball contacts, and dielectric layers, on a substrate;

FIG. 3B shows a cross-sectional view of the device of FIG. 3A;

FIG. 4A shows a top view of a device of the present disclosure, particularly showing an extension of the stiffener (i.e., stiffener extension);

FIG. 4B shows a cross-sectional view of the device of FIG. 4A, particularly showing the stiffener extension;

FIG. 5 shows a device of the present disclosure, particularly showing the stiffener extension over a mold frame;

FIG. 6 shows a device of the present disclosure, particularly showing a power multiplexer in the substrate; and

FIG. 7 is a diagram showing a method of the present disclosure for forming a device of the present disclosure.

### DETAILED DESCRIPTION

The following detailed description refers to the accompanying drawings that show, by way of illustration, specific details and aspects in which the present disclosure may be practiced. These aspects are described in sufficient detail to enable those skilled in the art to practice the present disclosure. Various aspects are provided for devices, and various aspects are provided for methods. It will be understood that the basic properties of the devices also hold for the methods and vice versa. Other aspects may be utilized and structural, and logical changes may be made without departing from the scope of the present disclosure. The various aspects are not necessarily mutually exclusive, as some aspects may be combined with one or more other aspects to form new aspects.

The present disclosure generally relates to a device. The device may be an electronic device, such as a semiconductor device or an electronic package. In general, the device may include one or more dies electrically coupled to a substrate. The one or more dies may be surrounded, or partially surrounded, by a stiffener having a first stiffener surface and a second stiffener surface opposite to the first stiffener surface. The stiffener may be electrically coupled to the substrate through the first stiffener surface. The stiffener may include one or more electrically conductive pillars (i.e., one or more interconnects) extending through the stiffener from the first stiffener surface to the second stiffener surface, and vice versa. The one or more dies may be electrically coupled to the one or more interconnects via one or more metal traces. For example, one die may be electrically coupled to one interconnect via one metal trace. For example, multiple dies may be electrically coupled to one interconnect via one or more multiple traces. The metal traces may be embedded, or having a part embedded, in the substrate, and still able to electrically couple a die to an interconnect. The device may include one or more test points configured on the second stiffener surface and electrically coupled to the one or more interconnects. Each of the one or more test points may be configured as a ball contact (an electrically conductive metal contact shaped spherically or substantially spherical, e.g., a ball shape). The term “substantially spherical” herein refers to a shape that is not a perfect sphere.

In various examples, the device may include a power multiplexer (Pmux) embedded, or partially embedded, in the substrate. The Pmux may be electrically coupled to the one or more interconnects at a surface of the substrate which the one or more interconnects are configured on. This surface, which is proximal to the one or more interconnects, may be referred to in the present disclosure as “first surface”. The Pmux may electrically couple the one or more interconnects to one or more solder balls configured at a surface of the substrate. This surface, which is distal from the one or more interconnects, may be referred to in the present disclosure as “second surface”, wherein the second surface is opposite to the first surface.

In various examples, the substrate may be a package substrate.

Advantageously, the device may help to address any of the issues and limitations mentioned above. For example, the device may help to address any of the issues and limitations associated with space constraints encountered in traditional devices requiring considerable number of test pins.

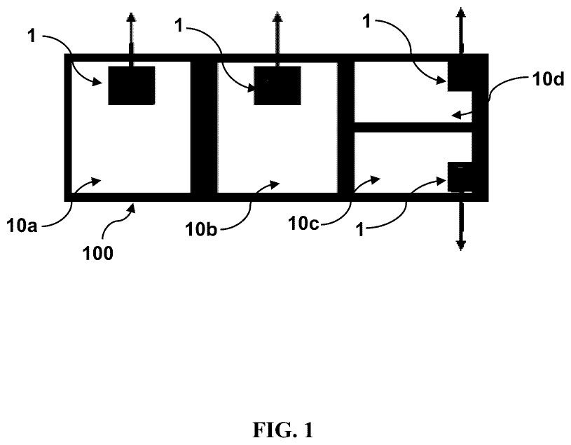

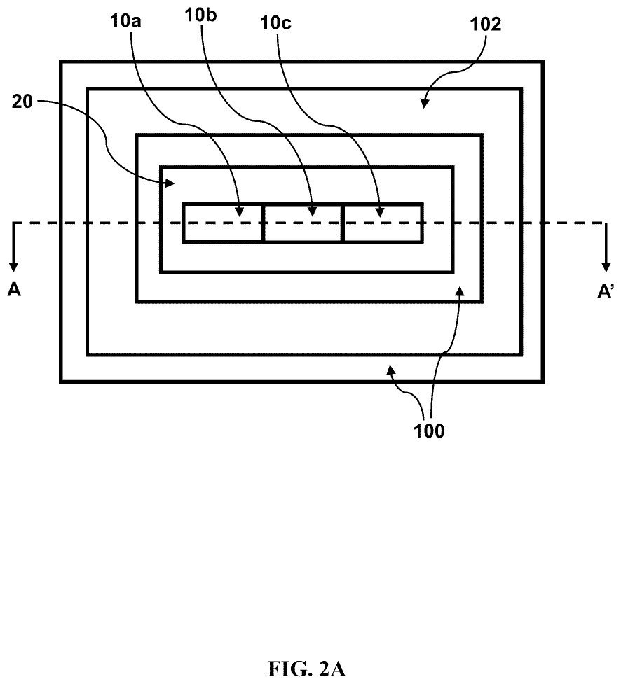

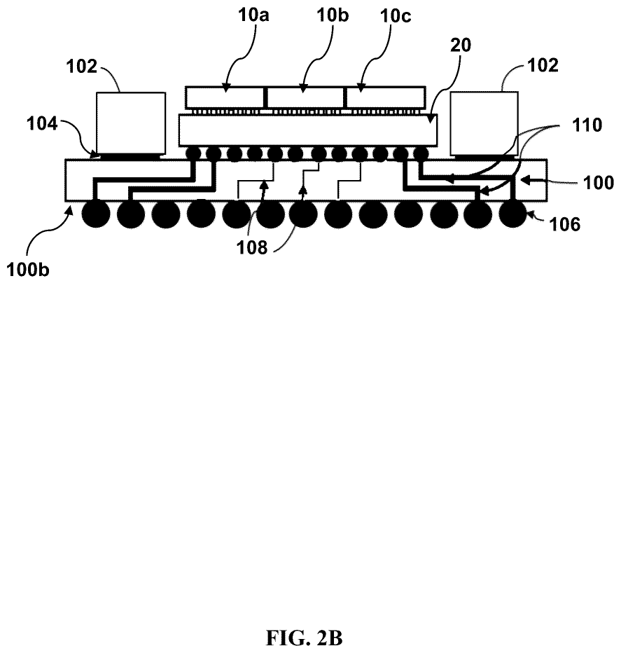

As mentioned above, traditionally, disaggregated die architecture tends to complicate production testing by requiring independent testing (hence a considerable testing duration) of each die even for parallel testing. This tends to increase the number of external package pins needed, likely leading to a larger footprint, more time, and higher costs. An example of such traditional architecture is shown in FIG. 1, depicting a traditional approach with dedicated test pins and/or test ports (TP, denoted reference numeral 1) for each die 10a, 10b, 10c, 10d for simultaneous dies testing. As more dies are integrated, e.g., in device with additional core compute dies, the complexity and size reduction challenges increase. 100 denotes the substrate which each of the dies 10a, 10b, 10c, 10d are configured on. FIG. 2A (top view) and 2B (cross-sectional view along the line A-A′ shown in FIG. 2A) further illustrate the die layout and architecture in a traditional device, respectively. It can be seen in FIGS. 2A and 2B that space on the substrate 100 may be limited, which tends to be a constraint that traditional devices may suffer from if more dies 10a, 10b, 10c are added to the existing architecture, in turn limiting the space available for test pins. 20 denotes a base die which the dies 10a, 10b, 10c are configured on, wherein the base die 20 is configured on the substrate 100. 102 denotes a traditional stiffener. In FIG. 2B, already, the traditional device includes on the substrate 100, a base die 20 having multiple dies 10a, 10b, 10c formed thereon, and a stiffener 102 adhered via an adhesive 104 to the substrate 100, wherein the stiffener 102 surrounds the base die 20. At the underside of the substrate 100 (i.e., second surface 100b), solder balls 106 are configured. The substrate 100 may include (i) metal traces 110 that electrically couple the dies to the solder balls 106 (e.g., to facilitate testing of the dies 10a, 10b, 10c) and (ii) signal routing lines 108. The solder balls 106 may serve as test points for the dies 10a, 10b, 10c. The signal routing lines 108 may relay signals received at the solder balls 106 to and/or from the dies 10a, 10b, 10c.

The device of the present disclosure, advantageously, reduces testing duration and package size. Said differently, device of the present disclosure addresses the extensive testing duration faced in traditional devices, incorrect sacrifices of dies that should have been tested, and aids in device miniaturization and cost reduction.

With regard to test time reduction, the present device allows higher testing bandwidth, as the device enables multi-die concurrent testing, involves high density stiffener test pins or class-probe-able pins (ascribed to tighter pitch compared to traditional solder balls 106 as shown in FIG. 2B). Particularly, physical isolation of power rails enables accurate system level power measurements on any die independently of other dies that share the same power supply at the package level. This capability accelerates power debug and power correlation exercises. The device also enables measuring standby current (SICC) at a per die power supply granularity.

With regard to device miniaturization, test interface units and/or test only pins can be routed to the stiffener through the substrate top side (first surface), hence does not compete for real estate or footprint with signal, power and ground pins, which may in turn save, for example, 30 mm² to 70 mm², by removing the test pins from the substrate.

In summary, the device described in aspects of the present disclosure may help to address and/or circumvent any of the issues and limitations mentioned above.

The present disclosure also relates to a method for forming the device. Understandably, the method described in aspects of the present disclosure may help to address and/or circumvent any of the issues and limitations mentioned above.

To more readily understand and put into practical effect the present disclosure, particular aspects will now be described by way of examples and not limitations, and with reference to the drawings. For the sake of brevity, duplicate descriptions of features and properties may be omitted.

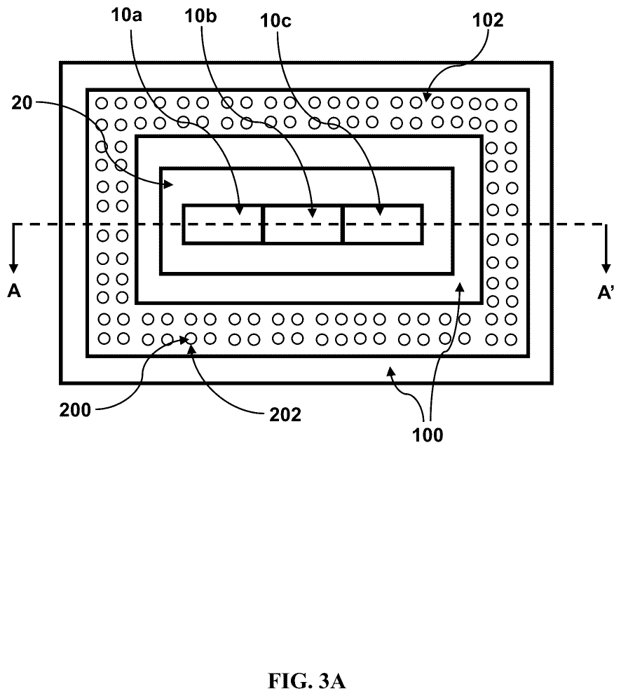

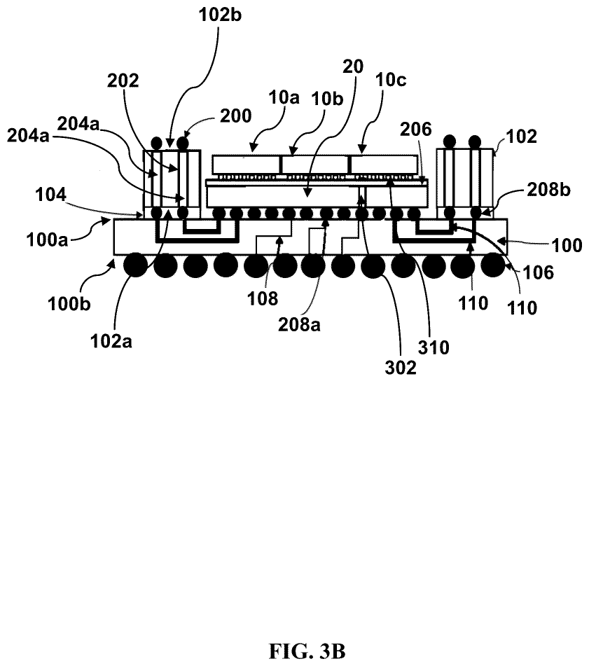

FIG. 3A shows a top view of a device of the present disclosure. FIG. 3A shows the layout of the stiffener 102, ball contacts 200, dielectric layers 202, and dies 10a, 10b, 10c configured on a base die 20 on the substrate 100. The device allows multiple dies to be concurrently tested, even when the device is miniaturized compared to traditional devices. The line A-A′ denotes a cross-sectional view of the device architecture shown in FIG. 3B.

FIG. 3B shows the cross-sectional view of the device of FIG. 3A. One or more dies 10a, 10b, 10c may be electrically coupled to the base die 20 via one or more micro-bumps 310. The one or more dies 10 a, 10 b, 10 c may be electrically coupled to the substrate 100 via a base die 20, solder bumps (i.e., first solder bumps 208a) which the base die 20 may be configured on, and/or one or more vias 302 which extend vertically across the base die (e.g., through-silicon via denoted as TSV). There may be a metal redistribution layer 206 configured between the various dies 10a, 10b, 10c and the base die 20 to further electrically couple the one or more dies 10a, 10b, 10c to the base die 20. The base die 20 may be electrically coupled to solder balls 106 through signal routing lines 108 and the solder bumps 208a. The base die 20 may be electrically coupled to one or more interconnects 204a via metal traces 110. Each interconnect 204a may be isolated from one another and/or the stiffener 102 through the dielectric layer 202. There may be a ball contact 200 on each interconnect 204a at the second stiffener surface 102b. The interconnect 204a may be adhered to the first surface 100 a of the substrate 100 via an adhesive 104, wherein in the adhesive 104 there may be a second solder bump 208b to each interconnect 204a electrically coupling the interconnect 204a to the base die 20 (and hence the dies 10a, 10b, 10c). In various examples, the substrate 100 may have a stiffener 102 that extends at least partially surrounding a die 10a, 10b, 10c, and the base die 20. In various examples, the stiffener 102 may have a first stiffener surface 102a and a second stiffener surface 102b opposite to the first stiffener surface 102a. There may be a plurality of interconnects 204a extending through the stiffener 102 from the first stiffener surface 102a to the second stiffener surface 102b, or vice versa. In various examples, the interconnects 204a may be isolated from the stiffener 102 by dielectric layers 202. The dielectric layers 202 may include epoxy resin (e.g., bismaleimide-triazine epoxy), polyamide, polyimide, polyethylene, ceramic, silicon dioxide, a polypropylene, a polyimide, and/or a polyester. In various examples, the stiffener 102 may have a thickness ranging from, for example, 100 μm to 700 μm, 200 μm to 700 μm, 300 μm to 700 μm, 400 μm to 700 μm, 500 μm to 700 μm, or 600 μm to 700 μm. The thickness of a stiffener 102 in the present disclosure is taken as the vertical distance (height) of the stiffener 102. In various examples, the stiffener 102 may be formed of aluminum or steel (e.g., stainless steel). In various examples, the first interconnects 204a may be electrically coupled to a plurality of metal traces 110 extending between the first surface 100a and second surface 100b of the substrate 100. In various examples, the first interconnects 204a may be electrically coupled to metal traces 110 through second solder bumps 208b at the first stiffener surface 102a. The one or more second solder bumps 208 b may be at least partially encapsulated by an adhesive 104, wherein the adhesive 104 may be, e.g., an epoxy such as an epoxy polymer resin with silica filler. In various examples, the adhesive 104 may include or may be an epoxy, epoxy cement, urethane, polyimide, polyvinyl chloride (PVC), polyethylene (PE), an acrylic or polyester. In various examples, the adhesive 104 may be a film. In various examples, the one or more metal traces 110 may include or may help to relay a signal associated with one or more of the following: digital linear voltage regulator (DLVR), high performance test port (HPTP), a joint test action group (JTAG) such as a platform controller die joint test action group (PCD JTAG), edge damage monitor (EDM), early power domain (EPD), and/or voltage interface for external verification (VIEW) so as to facilitate functionality validation of the one or more dies. In various examples, a plurality of input/output (I/O) signals (e.g., through signal routing lines 108) may be electrically coupled to the second surface 100b for communication with other electronic devices or components, e.g., a DRAM memory, a universal serial bus (USB) 3.0/4.0 connector, or a display panel electrically coupled to a printed circuit board (PCB), or a motherboard (all not shown). In various examples, the one or more mini balls (i.e., the ball contacts 200) may have a diameter ranging from, for example, 50 μm to 150 μm, 50 μm to 100 μm, or 100 μm to 150 μm. The one or more ball contacts 200 may be configured on each of the first interconnects 204a at the second stiffener surface 102b. In various examples, the plurality of ball contacts 200 may provide an access point for a tester to access circuitry block in the one or more dies 10a, 10b, 10c.

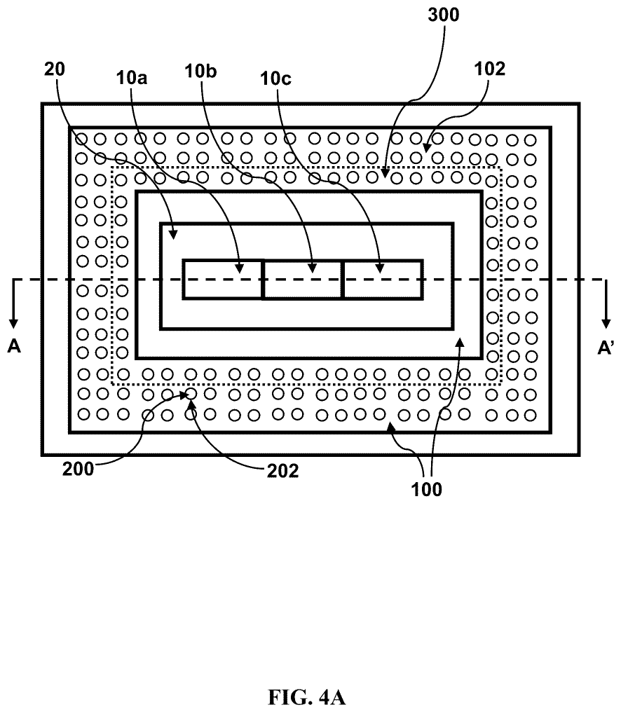

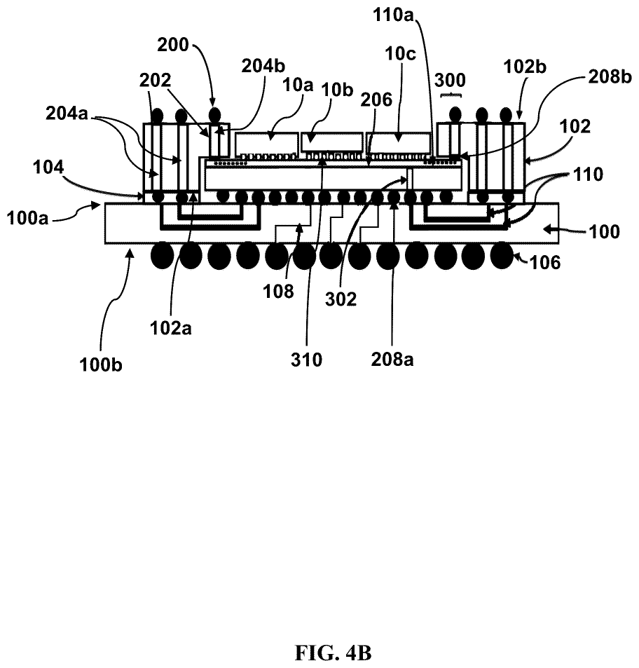

FIG. 4A shows a top view of a device of the present disclosure. The same reference numerals may be used to denote the same elements shown in the other figures, e.g., FIG. 3A, and hence for brevity shall not be reiterated in the figure due to any space constraint (and hence not reiterated in the description). The line A-A′ denotes a cross-sectional view of the device architecture shown in FIG. 4B. Particularly, FIG. 4A shows an extension of the stiffener 102 (i.e., stiffener extension 300 which is demarcated by the dotted line). The stiffener extension 300 may be structurally configured identical to the stiffener 102. That is to say, the stiffener extension 300 may include one or more interconnects (not shown), dielectric layers isolating the one or more interconnects (not shown) from the stiffener extension 300, and ball contacts 200. The ball contacts 200 are denoted by the circle dots in the demarcated region.

FIG. 4B shows a cross-sectional view of the device of FIG. 4A. The same reference numerals may be used to denote the same elements shown in the other figures, e.g., FIG. 3A and FIG. 3B, and hence for brevity shall not be reiterated in the figure due to any space constraint (and hence not reiterated in the description). Particularly, FIG. 4B shows examples of the device wherein the stiffener 102 further includes a stiffener extension 300 extending at least partially over the base die. The stiffener extension 300 may include one or more interconnects 204b (referred to as the one or more second interconnects 204b) extending through the first stiffener surface 102a and the second stiffener surface 102b of the stiffener extension 300. In various examples, the one or more second interconnects 204b may be electrically coupled to a metal redistribution layer (RDL) 206 of the base die 20 at the first stiffener surface 102a of the stiffener extension 300. In various examples, the one or more second interconnects 204b may be electrically coupled to one or more dies 10a, 10b, 10c configured on the base die 20 through one or more metal traces 110a or metal planes (not shown) in the metal RDL 206 and through one or more micro-bumps 310 (the micro-bumps 310 may be sandwiched between and in contact with a die 10 a, 10 b, 10 c and the base die 20). In various examples, one or more ball contacts 200 may be electrically coupled to one or more of the first interconnects 204a at the second stiffener surface 102b of the stiffener 102 and the one or more second interconnects 204b at the second stiffener surface 102b of the stiffener extension 300. In various examples, the second stiffener surface 102b of stiffener 102 may be levelled with the second stiffener surface 102b of the stiffener extension 300. In various examples, the ball contacts 200 may provide an access point for a tester to access circuitry block in the one or more dies 10a, 10b, 10c configured on the base die 20 without going through the substrate 100 (e.g., package substrate) and/or the TSV 302 path, allowing higher bandwidth for circuitry testing or validation for comprehensive product qualification. In various examples, the stiffener extension 300 may include a thickness ranging from, for example, 50 μm to 200 μm, 100 μm to 200 μm, 150 μm to 200 μm, 50 μm to 100 μm, or 50 μm to 150 μm. The thickness of the stiffener extension 300 in the present disclosure is taken as the vertical distance (height) of the stiffener extension 300. In various examples, the one or more first interconnects 204a may include a first diameter ranging from, for example, 100 μm to 200 μm, 150 μm to 200 μm, or 100 μm to 150 μm. In various examples, the one or more second interconnects 204b may include a second diameter smaller than the first diameter, e.g., in a range of 10 μm to 100 μm, 10 μm to 50 μm, or 50 μm to 100 μm. 208 b denotes the one or more second solder bumps for the stiffener 102 and for the stiffener extension 300.

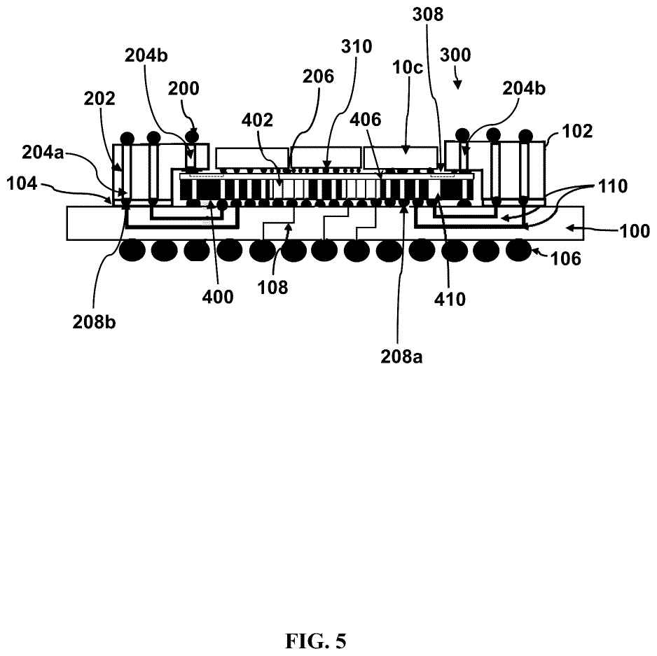

FIG. 5 shows a device of the present disclosure. The same reference numerals may be used to denote the same elements shown in the other figures, e.g., FIG. 3A to FIG. 3B and FIG. 4A to FIG. 4B, and hence for brevity shall not be reiterated in the figure due to any space constraint (and hence not reiterated in the description). Particularly, FIG. 5 shows the stiffener extension 300 may be extended over a mold frame 400. The mold frame 400 may include the base die 20 or serve as the base die 20. The mold frame 400 may be an alternative to house a plurality of smaller base dies (e.g., for cost reduction) in place and/or to provide direct electrical connection between the substrate 100 and dies 10a, 10b, 10c, i.e., without going through the base die 20 (e.g., for power delivery performance). For example, through mold via (TMV) with larger diameter or volumetric dimensions, such as that shown in the mold frame 400 of FIG. 5, may allow higher current carrying capacity compared to miniaturized TSV. The mold frame 400 may include epoxy polymer resin and/or a silica-based material. In various examples, the one or more second interconnects 204b may be electrically coupled to a metal redistribution layer (RDL) 206 horizontally extending on a bridge 402 (e.g., silicon bridge or in base die) and the mold frame 400. In various examples, the one or more second interconnects 204b may be electrically coupled to one or more dies configured on the metal RDL 206. 410 denotes a copper pillar in the mold frame 400, which may act as a through mold via that electrically couples the metal redistribution layer 206 (and hence the dies 10a, 10b, 10c) to one or more of the first interconnects 204a and/or one or more of the second interconnects 204b. 308 denotes a test signal relayed through the metal redistribution layer 206 from die 10c to a second interconnect 204b of the stiffener extension 300. 406 denotes a dielectric material isolating one via (e.g., the copper pillar 410) from another via in the mold frame 400 and/or isolate one via from the mold frame 400, e.g., the dielectric material 406 may sandwich one via. The dielectric material 406 may include or may be an epoxy resin, polyester, polypropylene, polyamide, polyimide, polyethylene, ceramic, and/or silicon dioxide.

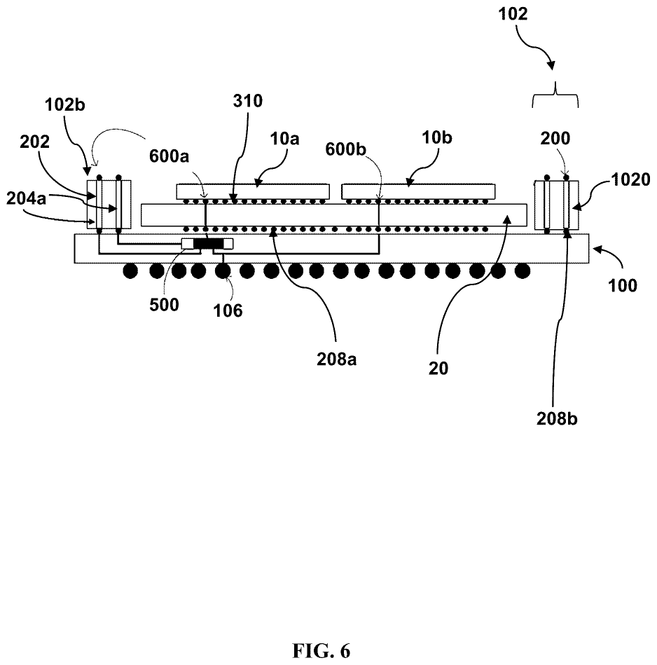

FIG. 6 illustrates an example of the device of the present disclosure. The same reference numerals may be used to denote the same elements shown in the other figures, e.g., FIG. 3A to FIG. 3B and FIG. 4A to FIG. 4B and FIG. 5, and hence for brevity shall not be reiterated in the figure due to any space constraint (and hence not reiterated in the description). Particularly, FIG. 6 shows the substrate 100 further includes a power multiplexer 500 (e.g., an analog power multiplexer (Pmux)). In various examples, the Pmux 500 may be embedded, or partially embedded, in the substrate 100. In various examples, the Pmux 500 may be configured in a bridge (not shown), e.g., a silicon bridge. In various examples, the power multiplexer 500 may be electrically coupled to both the one or more first interconnects 204a and the one or more dies 10a, 10b configured on the base die 20. The Pmux 500 may further include a power mux control (ctrl) (not shown) electrically coupled to the one or more first interconnects 204a. In various examples, the Pmux 500 may be configured to facilitate power or current measurements. In various examples, the stiffener 102 may include an organic mold frame 1020. In various examples, the Pmux 500 may be configured such that a first power plane (e.g., vdd1 denoted 600a) and a second power plane (e.g., vdd2 denoted 600b) may be merged at the substrate 100 (default state). The power or current measurements may be performed through the solder balls 106 of a solder ball grid array (BGA), e.g., a vdd-merged BGA. In various examples, when the ctrl signal is triggered, the first power rail and second power rail may be isolated/disconnected to allow power/current measurements for the respective power rails, e.g., vdd1 600a and vdd2 600b, separately. The term “vdd” in the present disclosure denotes a power rail in the device. In this mode, the first power rail (e.g., vdd1 600a) may be accessible through the one or more first interconnects 204a at the second stiffener surface 102b while the second power rail, e.g., vdd2, may be accessible or can be measured through one or more solder balls 106 of the solder BGA e.g., vdd-merged BGA.

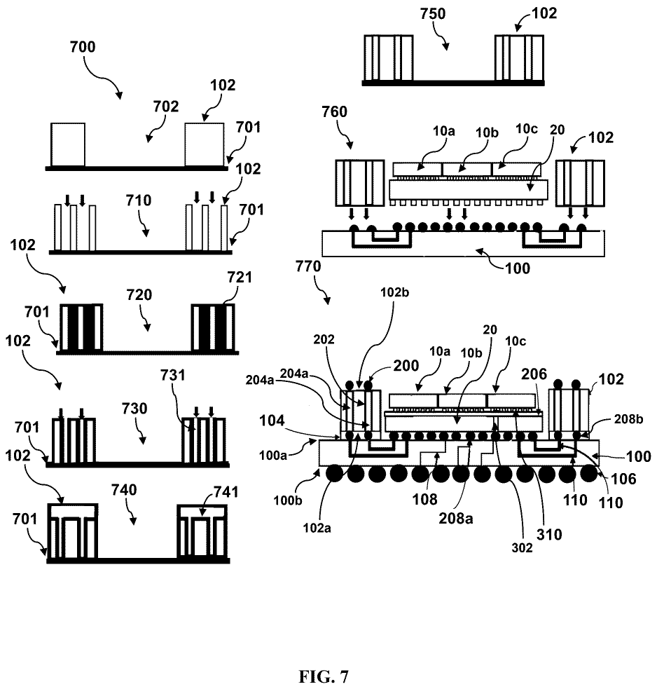

FIG. 7 is a diagram showing a method of the present disclosure. The same reference numerals may be used to denote the same elements shown in the other figures, e.g., FIG. 3A to FIG. 3B and FIG. 4A to FIG. 4B and FIG. 5, and hence for brevity shall not be reiterated in the figure due to any space constraint (and hence not reiterated in the description). The method may be used for forming the device of the present disclosure. The method may include forming 700 the stiffener 102 on a carrier 701 with a cavity 702 centrally configured in the stiffener 102. Any process traditionally used to form stiffener 102 may be used. The method may include forming 710 one or more channels in the stiffener 102, by removing parts of the stiffener 102 to define the one or more channels. The one or more channels may be formed by a process suitable to remove the parts, e.g., mechanical drilling, milling, or grinding. The method may include depositing 720 a dielectric material 721 into the one or more channels for forming the dielectric layers 202, which may be used to isolate the one or more first interconnects 204a from the stiffener 102. Deposition of the dielectric material 721 may be carried out using any known processes, where suitable. For example, deposition of the dielectric material 721 may be carried out by lamination, printing, or dispensing, the dielectric material 721 into the one or more channels. The method may include forming 730 a recess 731 in the dielectric material 721. The recess 731 may be formed using the same process used to form the one or more channels, for example, mechanical drilling, milling, or grinding. The method may include depositing 740 an interconnect material 741 into the recess 731 for forming the one or more first interconnects 204a. The interconnect material 741 may include or may be an electrically conductive material, such as copper. Deposition of the interconnect material 741 may be carried out by any known processes, for example, paste printing or electroplating. Any excess copper may be removed from the second stiffener surface 102b. Said differently, the method may include removing 750 any excess copper from the stiffener 102. The method may include configuring 760 the stiffener 102 and the base die 20 having one or more dies 10 a, 10 b, 10 c thereon on a substrate 100. The various components (e.g., the dies 10a, 10b, 10c on base die 20 as well as the first solder bumps 208a and second solder bumps 208b on the substrate 100) may be separately assembled by any suitable known processes. The various components, including the stiffener 102, may then be attached with the substrate 100. Such attaching may be carried out by any known processes, such as soldering (e.g., solder reflow) or thermal compression bonding. In other words, the method may include attaching 770 the stiffener 102 and the base die 20 to the substrate, for example, by using an adhesive and bonding (e.g., soldering), respectively. The method may include forming 770 the solder balls 200 on the one or more first interconnects 204a, for example, by any known processes, such as soldering (solder reflow) or by surface mounting.

Additional aspects of the disclosure will be demonstrated by way of non-limiting examples mentioned below.

Example 1 may include a device. In various aspects and examples, the device may include a substrate including a first surface and a second surface opposite to the first surface, a base die including dies (or one die) formed on the base die, wherein the base die may be electrically coupled to the first surface, and a stiffener adhered to the first surface, wherein the stiffener may be peripherally configured to the base die, wherein the stiffener may include a first interconnect (or multiple first interconnects) which extends through the stiffener from a first stiffener surface to a second stiffener surface, wherein the first interconnect may be electrically coupled to the base die via a metal trace (or multiple metal traces) embedded in the substrate.

Example 2 may include the device of example 1 and/or any other example disclosed herein, further including signal routing lines embedded (or partially embedded) in the substrate, wherein the signal routing lines extend through the substrate from the first surface to the second surface.

Example 3 may include the device of example 2 and/or any other example disclosed herein, wherein the second surface may include a ball grid array distal from the base die, wherein the ball grid array may include solder balls, wherein at least one of the solder balls may be electrically coupled to a first solder bump configured between the base die and the substrate via one of the signal routing lines.

Example 4 may include the device of example 1 and/or any other example disclosed herein, wherein the stiffener may include aluminum or steel.

Example 5 may include the device of example 1 and/or any other example disclosed herein, further including two dielectric layers, wherein the first interconnect may be configured between the two dielectric layers, and wherein each of the two dielectric layers may be configured adjacent to (and/or in contact with) the first interconnect so as to isolate the first interconnect from the stiffener.

Example 6 may include the device of example 5 and/or any other example disclosed herein, wherein each of the two dielectric layers may include an epoxy resin, polyester, polypropylene, polyamide, polyimide, polyethylene, ceramic, or silicon dioxide.

Example 7 may include the device of example 5 and/or any other example disclosed herein, further including a layer of adhesive between and in contact with the first surface and the first stiffener surface, wherein the layer of adhesive may include a second solder bump which corresponds in position to the first interconnect exposed at the first stiffener surface to electrically couple the first interconnect to the metal trace.

Example 8 may include the device of example 7 and/or any other example disclosed herein, wherein the layer of adhesive may include epoxy, epoxy cement, urethane, polyimide, polyvinyl chloride, polyethylene, an acrylic, or polyester.

Example 9 may include the device of example 7 and/or any other example disclosed herein, further including a metal redistribution layer between the base die and the dies, wherein the metal redistribution layer may electrically couple the base die and the dies.

Example 10 may include the device of example 9 and/or any other example disclosed herein, wherein the stiffener may include a portion (i.e., the stiffener extension) which extends vertically above the base die, wherein the portion may include a second interconnect configured between two dielectric layers adjacent to the second interconnect so as to isolate the second interconnect from the stiffener and the second interconnect extends from the first stiffener surface to the second stiffener surface, wherein at the first stiffener surface one second solder bump corresponds in position to the second interconnect exposed at the first stiffener surface to electrically couple the second interconnect to the metal redistribution layer.

Example 11 may include the device of example 9 and/or any other example disclosed herein, further including a via which extends across the base die, wherein the via may electrically couple the dies to the first interconnect through the metal redistribution layer and the metal trace.

Example 12 may include the device of example 10 and/or any other example disclosed herein, wherein the metal redistribution layer may include a silicon die and the second interconnect may be electrically coupled to the silicon die.

Example 13 may include the device of example 10 and/or any other example disclosed herein, further including a mold frame which may include the base die and/or a bridge, wherein the base die or bridge may extend across the mold frame, electrically coupling the first solder bumps to the metal redistribution layer.

Example 14 may include the device of example 10 and/or any other example disclosed herein, wherein the first interconnect and the second interconnect each may include an exposed surface at the second stiffener surface with one ball contact corresponding in position to and in contact with each exposed surface.

Example 15 may include the device of example 10 and/or any other example disclosed herein, wherein the portion may include a thickness in a range of 50 μm to 200 μm, and/or wherein the stiffener may include a thickness in a range of 100 μm to 700 μm. The term “thickness” is already described above and hence, for brevity, shall not be reiterated.

Example 16 may include the device of example 1 and/or any other example disclosed herein, wherein the substrate may include a power multiplexer electrically coupled to the first interconnect, the base die, the dies, and/or the second surface.

Example 17 may include the device of example 1 and/or any other example disclosed herein, wherein the dies may include a central processing unit, a system-on-chip, a graphic processing unit, a neural network processing unit, a tensor processing unit, or a memory unit.

Example 18 may include a method. The method may be a method for forming the device of example 1 and/or any other example disclosed herein. The method may include forming on a carrier a stiffener with a cavity configured (e.g., centrally) in the stiffener, removing a part of the stiffener to define a channel which extends vertically across the stiffener from a first stiffener surface to a second stiffener surface, forming in the channel a first interconnect sandwiched between two dielectric layers to isolate the first interconnect from the stiffener, and configuring the stiffener and a base die on a substrate, wherein the base die may include dies formed on the base die.

Example 19 may include the method of example 18 and/or any other example disclosed herein, wherein forming in the channel the first interconnect sandwiched between two dielectric layers (to isolate the first interconnect from the stiffener) may include depositing a dielectric material in the channel, removing a part of the dielectric material to define a recess which is identical in height as the channel, and depositing an interconnect material in the recess to form the first interconnect.

Example 20 may include the method of example 18 and/or any other example disclosed herein, wherein configuring the stiffener and the base die on the substrate may include aligning the first interconnect to correspond in position with one second solder bump on the substrate, aligning the base die to correspond in position with first solder bumps on the substrate, adhering the stiffener to the substrate, and bonding the base die to the first solder bumps.

The term “electrically couple” in the present disclosure means that two or more components or elements may be connected in any manner such that electricity can be transmitted between the two or more components. For example, component or element A electrically coupled to component or element B means that electricity can be transmitted between component or element A and component or element B. The connection may be established through an electrically conductive medium, e.g., a metal wire or a layer of metal that conducts electricity.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

While the present disclosure has been particularly shown and described with reference to specific aspects, it should be understood by persons skilled in the art that various changes in form and detail may be made therein without departing from the scope of the present disclosure as defined by the appended claims. The scope of the present disclosure is thus indicated by the appended claims and all changes which come within the meaning and range of equivalency of the claims are therefore intended to be embraced.

What is claimed is:

1. A device comprising:
a substrate comprising a first surface and a second surface opposite to the first surface;
a base die comprising dies formed on the base die, wherein the base die is electrically coupled to the first surface; and
a stiffener adhered to the first surface, wherein the stiffener is peripherally configured to the base die, wherein the stiffener comprises a first interconnect which extends through the stiffener from a first stiffener surface to a second stiffener surface, wherein the first interconnect is electrically coupled to the base die via a metal trace embedded in the substrate.

2. The device of claim 1, further comprising signal routing lines embedded in the substrate, wherein the signal routing lines extend through the substrate from the first surface to the second surface.

3. The device of claim 2, wherein the second surface comprises a ball grid array distal to the base die, wherein the ball grid array comprises solder balls, wherein at least one of the solder balls is electrically coupled to a first solder bump configured between the base die and the substrate via one of the signal routing lines.

4. The device of claim 1, wherein the stiffener comprises aluminum or steel.

5. The device of claim 1, further comprising two dielectric layers, wherein the first interconnect is configured between the two dielectric layers, and wherein each of the two dielectric layers are configured adjacent to the first interconnect so as to isolate the first interconnect from the stiffener.

6. The device of claim 5, wherein each of the two dielectric layers comprises an epoxy resin, polyester, polypropylene, polyamide, polyimide, polyethylene, ceramic, or silicon dioxide.

7. The device of claim 5, further comprising a layer of adhesive between, and in contact with, the first surface and the first stiffener surface, wherein the layer of adhesive comprises a second solder bump which corresponds in position to the first interconnect exposed at the first stiffener surface to electrically couple the first interconnect to the metal trace.

8. The device of claim 7, wherein the layer of adhesive comprises epoxy, epoxy cement, urethane, polyimide, polyvinyl chloride, polyethylene, an acrylic, or polyester.

9. The device of claim 7, further comprising a metal redistribution layer between the base die and the dies, wherein the metal redistribution layer electrically couples the base die and the dies.

10. The device of claim 9, wherein the stiffener comprises a portion which extends vertically above the base die, wherein the portion comprises a second interconnect configured between two dielectric layers adjacent to the second interconnect so as to isolate the second interconnect from the stiffener and the second interconnect extends from the first stiffener surface to the second stiffener surface, wherein at the first stiffener surface one second solder bump corresponds in position to the second interconnect exposed at the first stiffener surface to electrically couple the second interconnect to the metal redistribution layer.

11. The device of claim 9, further comprising a via which extends across the base die, wherein the via electrically couples the dies to the first interconnect through the metal redistribution layer and the metal trace.

12. The device of claim 10, wherein the metal redistribution layer comprises a silicon die and the second interconnect is electrically coupled to the silicon die.

13. The device of claim 10, further comprising a mold frame, which comprises the base die and/or a bridge, wherein the base die or bridge extends across the mold frame, electrically coupling first solder bumps to the metal redistribution layer.

14. The device of claim 10, wherein the first interconnect and the second interconnect each comprises an exposed surface at the second stiffener surface with one ball contact corresponding in position to and in contact with each exposed surface.

15. The device of claim 10, wherein the portion comprises a thickness in a range of 50 μm to 200 μm, and/or wherein the stiffener comprises a thickness in a range of 100 μm to 700 μm.

16. The device of claim 1, wherein the substrate comprises a power multiplexer electrically coupled to the first interconnect, the base die, the dies, and/or the second surface.

17. The device of claim 1, wherein the dies comprise a central processing unit, a system-on-chip, a graphic processing unit, a neural network processing unit, a tensor processing unit, or a memory unit.

18. A method comprising:
forming on a carrier a stiffener with a cavity configured in the stiffener;
removing a part of the stiffener to define a channel, which extends vertically across the stiffener from a first stiffener surface to a second stiffener surface;
forming in the channel a first interconnect sandwiched between two dielectric layers to isolate the first interconnect from the stiffener; and
configuring the stiffener and a base die on a substrate, wherein the base die comprises dies formed on the base die.

19. The method of claim 18, wherein forming in the channel the first interconnect sandwiched between two dielectric layers to isolate the first interconnect from the stiffener comprises:
depositing a dielectric material in the channel;
removing a part of the dielectric material to define a recess which is identical in height as the channel; and
depositing an interconnect material in the recess to form the first interconnect.

20. The method of claim 18, wherein configuring the stiffener and the base die on the substrate comprises:
aligning the first interconnect to correspond in position with one second solder bump on the substrate;
aligning the base die to correspond in position with first solder bumps on the substrate;
adhering the stiffener to the substrate; and
bonding the base die to the first solder bumps.
